(19) United States
(12) Patent Application Publication
(10) Pub. No.: US 2026/0068645 A1
(43) Pub. Date: Mar. 5, 2026

(54) GATE CONTACT STRUCTURE AND METHOD OF MANUFACTURING THE SAME

(71) Applicant: Samsung Electronics Co., Ltd., Suwon-si (KR)

(72) Inventors: Deokhwan KIM, Suwon-si (KR); Sungmin KIM, Suwon-si (KR); Jaemyeong KIM, Suwon-si (KR); Jeonggeol KIM, Suwon-si (KR); Yongkyung LEE, Suwon-si (KR)

(73) Assignee: Samsung Electronics Co., Ltd., Suwon-si (KR)

(21) Appl. No.: 19/314,452

(22) Filed: Aug. 29, 2025

(30) Foreign Application Priority Data
Sep. 3, 2024 (KR) 10-2024-0119556

(51) Int. Cl. H01L 23/528; H01L 21/768; H01L 23/532; H10D 30/01; H10D 30/62; H10D 64/27

(52) U.S. Cl. CPC H01L 23/5283; H10D 30/024; H10D 64/518; H10D 30/6211

(57) ABSTRACT

Provided are a gate contact structure and a method of manufacturing the gate contact structure. The gate contact structure includes a gate electrode, an etch stop layer provided on the gate electrode, a capping layer provided on the etch stop layer, a contact hole including a first portion provided in the etch stop layer and coming in contact with the gate electrode and a second portion provided in the capping layer and communicating with the first portion, and a gate contact plug provided in the contact hole. A width of the first portion is greater than a width of the second portion.

### CROSS-REFERENCE TO RELATED APPLICATION

This application is based on and claims priority under 35 U.S. C. § 119 to Korean Patent Application No. 10-2024-0119556, filed on Sep. 3, 2024, in the Korean Intellectual Property Office, the disclosure of which is incorporated by reference herein in its entirety.

### BACKGROUND

### 1. Field

The disclosure relates to a gate contact structure and a method of manufacturing the same, and more particularly, to a contact structure of a gate electrode and a gate contact plug and a method of manufacturing the contact structure.

### 2. Description of the Related Art

In the electronics industry, the demand for smaller, faster electronic devices capable of simultaneously supporting numerous functions continues to increase. Accordingly, the semiconductor industry continues to pursue the trend toward manufacturing low-cost, high-performance, low-power integrated circuits (ICs). Up to now, such goals have been largely achieved by reducing semiconductor IC dimensions (e.g., a minimum feature size) to improve the production efficiency and lower the associated costs. However, this expansion has complicated the semiconductor manufacturing processes. Therefore, for continuous advancements in semiconductor ICs and devices, similar advancements in semiconductor manufacturing processes and technologies are being explored.

As IC devices continue to become smaller, the dimensions of contact features source/drain contact vias and gate contact features are becoming smaller, and defects such as over-etching or under-etching of a capping layer on an electrode may occur during a gate contact process. Therefore, there is a need for a gate contact structure enabling a low-power, high-speed operation of a device while lowering the contact resistance and a method of manufacturing the gate contact structure.

### SUMMARY

Provided are a gate contact structure and a method of manufacturing the same, wherein a phenomenon in which a capping layer is not sufficiently etched or is over-etched up to a gate electrode due to the thickness and dispersion of the capping layer when forming a contact hole in a semiconductor structure may be prevented and/or mitigated; and a contact resistance may be further improved.

Additional aspects will be set forth in part in the description which follows and, in part, will be apparent from the description, or may be learned by practice of the presented embodiments of the disclosure.

According to an aspect of the disclosure, provided is a gate contact structure including a gate electrode, an etch stop layer above the gate electrode, a capping layer above the etch stop layer, a contact hole including a first portion defined by the etch stop layer and in contact with the gate electrode and a second portion defined by the capping layer and communicating with the first portion, and a gate contact plug in the contact hole, wherein a width of the first portion is greater than a width of the second portion.

The first portion of the contact hole may include a first part adjacent to the capping layer and a second part adjacent to the gate electrode, and a width of the first part of the first portion adjacent may be greater than a width of the second part of the first portion.

A width of the first part of the first portion may be equal to a width of the part of the first portion.

The etch stop layer may include an extension portion extending in a direction perpendicular to a surface of the gate electrode.

The capping layer may include SiN and the etch stop layer may include at least one of SiO₂, SiOCN, SiON, SiOC, SiCN, or a combination thereof.

The etch stop layer may include a first etch stop layer and a second etch stop layer, wherein the first etch stop layer may be above the gate electrode and the second etch stop layer may be above the first etch stop layer.

The capping layer may include SiN, the first etch stop layer may include at least one of AlO, AlN, TiO₂, TiN, SiO₂, or a combination thereof, and the second etch stop layer may include at least one of SiO₂, SiOCN, SiON, SiOC, SiCN, or a combination thereof.

The first portion of the contact hole may be provided in the second etch stop layer and may include a first part adjacent to the capping layer and a second part adjacent to the gate electrode, the contact hole may further include a third portion provided in the first etch stop layer, and a width of the third portion may be greater than the width of the first portion.

The first portion of the contact hole may be in the second etch stop layer and may include a first part adjacent to the capping layer and a second part adjacent to the gate electrode, the contact hole may further include a third portion provided in the first etch stop layer, a width of the second part of the first portion may be greater than a width of the first part of the first portion, and a width of the third portion may be equal to the width of the second part of the first portion.

The first portion may be in the second etch stop layer, the contact hole may further include a third portion in the first etch stop layer, a width of the second part of the first portion may be greater than a width of the first part of the first portion, and a width of the third portion may be equal to the width of the second part of the first portion.

The first portion may be in the second etch stop layer, the contact hole may further include a third portion in the first etch stop layer, a width of the second part of the first portion may be greater than a width of the second part of the first portion, and a width of the third portion may be less than the width of the second part of the first portion.

According to another aspect of the disclosure, provided is a method of manufacturing a gate contact structure, the method including providing an etch stop layer on a gate electrode, providing a capping layer on the etch stop layer, forming a first portion of a contact hole by etching the capping layer, forming a second portion of the contact hole by etching the etch stop layer, and forming a gate contact plug within the contact hole, wherein a width of the first portion is greater than a width of the second portion.

The etching of the capping layer may include anisotropically etching the capping layer and the etching of the etch stop layer may include isotropically etching the etch stop layer.

The etching of the etch stop layer may include anisotropically etching the etch stop layer and isotropically etching the etch stop layer.

The providing of the etch stop layer on the gate electrode may include providing a first etch stop layer on the gate electrode and providing a second etch stop layer on the first etch stop layer, and the etching of the etch stop layer may include isotropically etching the second etch stop layer and isotropically etching the first etch stop layer.

The providing of the etch stop layer on the gate electrode may include providing a first etch stop layer on the gate electrode and providing a second etch stop layer on the first etch stop layer, and the etching of the etch stop layer may include anisotropically etching the second etch stop layer, isotropically etching the etched second etch stop layer, and isotropically etching the first etch stop layer.

The providing of the etch stop layer on the gate electrode may include providing a first etch stop layer on the gate electrode and providing a second etch stop layer on the first etch stop layer, and the etching of the etch stop layer may include isotropically etching the second etch stop layer, isotropically etching the first etch stop layer, and isotropically etching the etched first etch stop layer and the etched second etch stop layer together.

The providing of the etch stop layer on the gate electrode may include providing a first etch stop layer on the gate electrode and providing a second etch stop layer on the first etch stop layer, and the etching of the etch stop layer may include isotropically etching the second etch stop layer, isotropically etching the first etch stop layer, and anisotropically etching the etched second etch stop layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram schematically illustrating an overall configuration of a semiconductor structure according to at least one embodiment;

FIG. 2 is an on gate cut view of a gate contact structure according to at least one embodiment;

FIG. 3 is an on active cut cross-sectional view of the gate contact structure of FIG. 2;

FIGS. 4 to 10 are diagrams illustrating a method of manufacturing the gate contact structure of FIG. 1;

FIG. 11 is an on gate cut cross-sectional view of a gate contact structure according to at least one embodiment;

FIGS. 12 to 14 are diagrams illustrating a method of manufacturing the gate contact structure of FIG. 11;

FIG. 15 is an on gate cut cross-sectional view of a gate contact structure according to at least one embodiment;

FIG. 16 is an on active cut cross-sectional view of the gate contact structure of FIG. 15;

FIG. 17 is an on gate cut cross-sectional view of a gate contact structure according to at least one embodiment;

FIG. 18 is an on active cut cross-sectional view of the gate contact structure of FIG. 17;

FIG. 19 is an on gate cut cross-sectional view of a gate contact structure according to at least one embodiment;

FIG. 20 is an on active cut cross-sectional view of the gate contact structure of FIG. 19;

FIG. 21 is an on gate cut cross-sectional view of a gate contact structure according to at least one embodiment;

FIG. 22 is an on active cut cross-sectional view of the gate contact structure of FIG. 21;

FIG. 23 is an on gate cut cross-sectional view of a gate contact structure according to at least one embodiment; and

FIG. 24 is an on active cut cross-sectional view of the gate contact structure of FIG. 23.

### DETAILED DESCRIPTION

Reference will now be made in detail to embodiments, examples of which are illustrated in the accompanying drawings, wherein like reference numerals and like terminology refer to like elements throughout except where otherwise specified. Embodiments described herein are only examples and various modifications may be made thereto from these embodiments. In the following drawings, the size of each element in the drawings may be exaggerated for clarity and convenience of explanation. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Further, when referring to as “within a range of” “C to D”, this means C inclusive to D inclusive unless otherwise specified.

Hereinafter, the terms “above” or “on” may include not only those that are directly above, below, left, or right in a contact manner, but also those that are above, below, left, or right in a non-contact manner. For example, such directional terms, such as “above”, “below”, and/or similar directional terms, are intended to encompass different orientations of the device in use or operation in addition to the orientation depicted in the figures, and that the device may be otherwise oriented (rotated 90 degrees or at other orientations) and the spatially relative terms used herein interpreted accordingly.

The terms such as “first,” “second,” etc. may be used to describe various elements, but are only used to distinguish one element from another. These terms are not intended to limit different materials or structures of the elements.

The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

Also, the terms such as “unit” and “module” described in the specification mean units that process at least one function or operation, and may be implemented as processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components (such as at least one of transistors, resistors, capacitors, etc.), and/or electronic circuits including said components.

The use of the term “the” and similar demonstratives may correspond to both the singular and the plural. Also, the use of all illustrations or illustrative terms (for example, etc.) in the embodiments is simply to describe the technical ideas in detail, and the scope of the disclosure is not limited by the illustrations or illustrative terms unless they are limited by claims.

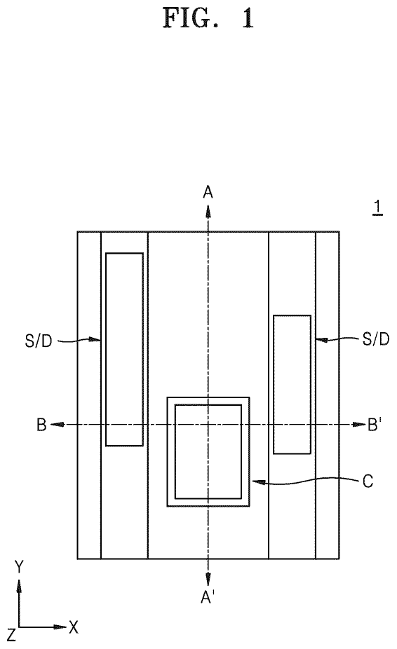

FIG. 1 is a diagram schematically illustrating an overall configuration of a semiconductor structure 1 according to at least one embodiment.

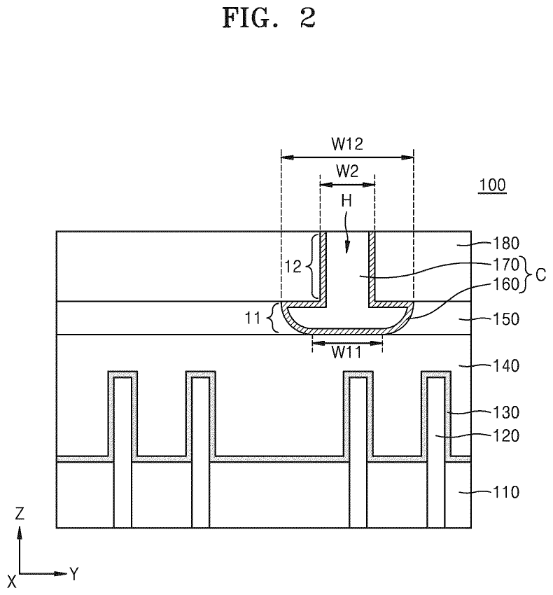

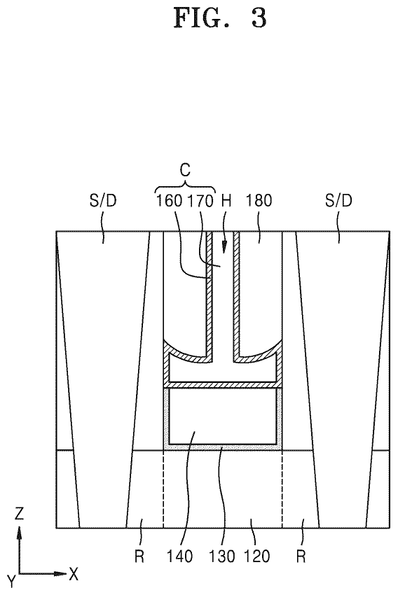

Referring to FIG. 1, the semiconductor structure 1 may include source/drain electrodes S/D and a gate contact plug C. The source/drain electrodes S/D may be apart from each other in a horizontal (e.g., X) direction. Source/drain regions (see R in FIG. 3) may be provided under the source/drain electrodes S/D. The gate contact plug C may be provided between the source/drain electrodes S/D. A channel (e.g., the channel 120 in FIGS. 2 and 3) may be provided between the source/drain regions. The source/drain electrodes S/D and the gate contact plug C may be provided in various layouts. For example, as illustrated in FIG. 1, one of the source/drain electrodes S/D and the gate contact plug C may be provided at different levels in a second horizontal (e.g., Y) direction, and the other of the source/drain electrodes S/D may be provided at a level between the one of the source/drain electrodes S/D and the gate contact plug C in the Y direction. However, this is only an example and the source/drain electrodes S/D and the gate contact plug C may be formed in various layouts. Hereinafter, the gate contact plug C, the gate electrode, and the components related thereto are mainly described. Hereinafter, a cross-section taken along line A-A′ of FIG. 1 is referred to as an on gate cut and a cross-section taken along line B-B′ of FIG. 1 is referred to as an on active cut.

FIG. 2 is an on gate cut view of a gate contact structure 100 according to at least one embodiment and FIG. 3 is an on active cut cross-sectional view of the gate contact structure 100. For convenience of explanation, some elements are omitted.

Referring to FIGS. 2 and 3, the gate contact structure 100 according to at least one embodiment may include a channel 120 provided on a substrate 110, an insulating layer 130 provided on the channel 120, and a gate electrode 140 provided on the insulating layer 130. In addition, an etch stop layer 150 may be provided on the gate electrode 140 and a capping layer 180 may be provided on the etch stop layer 150.

The substrate 110 may be an insulating substrate, and/or may be a semiconductor substrate with an insulating material formed on a surface thereof. Alternatively, the substrate 110 may be a semiconductor substrate. The semiconductor substrate may include, for example, an elemental semiconductor (e.g., Si, Ge, etc.) and/or a compound semiconductor (e.g., SiGe, a Group III-V semiconductor material, etc.). The substrate 110 may be, for example, a silicon substrate having silicon oxide formed on a surface thereof, but the disclosure is not limited thereto.

The channel 120 may include an amorphous oxide semiconductor. The channel 120 may include a material selected from, for example, InGaZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, zinc indium oxide (ZIO), indium gallium oxide (IGO), and/or a combination thereof. The channel 120 may be, for example, a fin channel formed to extend in a direction perpendicular to the substrate 110. Hereinafter, a fin field effect transistor (FinFET) structure is described as an example, but the following description may also be applied to various structures, including a gate-all-around (GAA) structure.

The gate electrode 140 may include at least one conductive material (e.g., zero-band gap and/or equivalent material) selected from metal, metal nitride, metal carbide, polysilicon, and/or a combination thereof. For example, the metal may include aluminum (Al), tungsten (W), molybdenum (Mo), titanium (Ti), tantalum (Ta) etc., the metal nitride film may include a titanium nitride (TiN) film, a tantalum nitride (TaN) film, etc., and the metal carbide may include TiAlC, TaAlC, TiSiC, TaSiC, etc.

The insulating layer 130 may be provided between the channel 120 and the gate electrode 140 to electrically disconnect the channel 120 and the gate electrode 140 from each other. In at least some embodiments, the insulating layer 130 may also be referred to as a gate dielectric. The insulating layer 130 may include an insulating material. The insulating layer 130 may include, for example, a dielectric. The insulating layer 130 may include, for example, a high-k material, such as aluminum oxide, hafnium (Hf) oxide, or titanium oxide, but the disclosure is not limited thereto.

The etch stop layer 150 may include a material having etch selectivity with respect to the capping layer 180. The etch stop layer 150 may include, for example, a material having a high selectivity. The selectivity indicates an etch rate ratio of the etch stop layer 150 to the capping layer 180. In at least some embodiments, wherein the capping layer 180 includes silicon nitride (e.g., SiN), the etch stop layer 150 may include at least one selected from SiO₂, SiOCN, SiON, SiOC, SiCN, and/or a combination thereof.

A contact hole H passing through the etch stop layer 150 and the capping layer 180 in a vertical (e.g., Z) direction may be provided. A gate contact plug C may be provided inside the contact hole H. The gate contact plug C may include a barrier metal 160 provided inside a region passing through the etch stop layer 150 and the capping layer 180 and a metal material 170 provided inside the barrier metal 160. The barrier metal 160 may include, for example, Ti or TiN. The metal material 170 may include, for example, W.

The contact hole H may include a first portion 11 passing through the etch stop layer 150 and a second portion 12 passing through the capping layer 180 and communicating with the first portion 11. The lower part of the first portion 11 may come in contact with the gate electrode 140. The lower part of the first portion 11 may be provided on the top surface of the gate electrode 140. The upper part of the first portion 11 may come in contact with the capping layer 180. The upper part of the first portion 11 may be provided below a bottom surface of the capping layer 180. Hereinafter, the upper part of the first portion 11 may refer to a part of the first portion 11 provided adjacent to the gate electrode 140, and the lower part of the first portion 11 may refer to a part of the first portion 11 provided adjacent to the capping layer 180. As illustrated in FIG. 2, a width W11 of the lower part of the first portion 11 may be greater than a width W12 of the upper part of the first portion 11.

A width W2 of the second portion 12 may be less than the widths W11 and W12 of the first portion 11. When viewed from the Z direction, the area of the first portion 11 of the contact hole H passing through the etch stop layer 150 may be greater than the area of the second portion 12 of the contact hole H passing through the capping layer 180.

In the gate contact structure 100 according to at least one embodiment, because the etch stop layer 150 having a relatively high selectivity with respect to the capping layer 180 is provided between the capping layer 180 and the gate electrode 140, a phenomenon in which the capping layer 180 is not sufficiently etched and/or is over-etched up to the gate electrode 140 due to the thickness and dispersion of the capping layer 180 when forming the contact hole H may be prevented and/or mitigated.

In addition, because the first portion 11 of the contact hole H provided in the etch stop layer 150 is formed to have a width greater than a width of the second portion 12 provided in the capping layer 180, the area where the gate contact plug C and the gate electrode 140 come in contact with each other may increase. Accordingly, the contact resistance of the gate contact structure 100 may decrease and the capacitance thereof may increase.

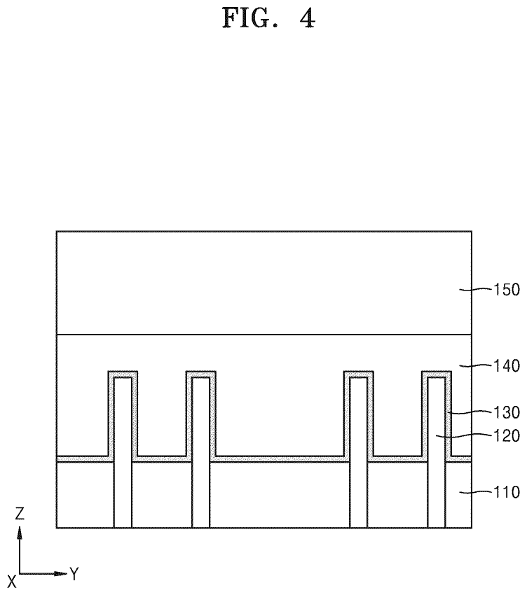

FIGS. 4 to 10 are diagrams illustrating a method of manufacturing the gate contact structure 100 of FIG. 1.

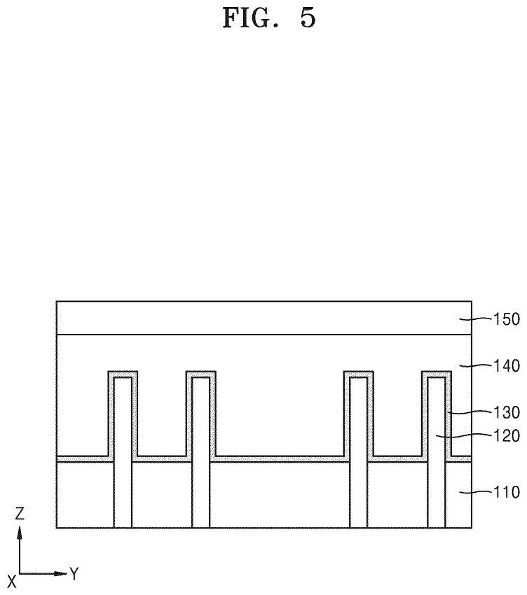

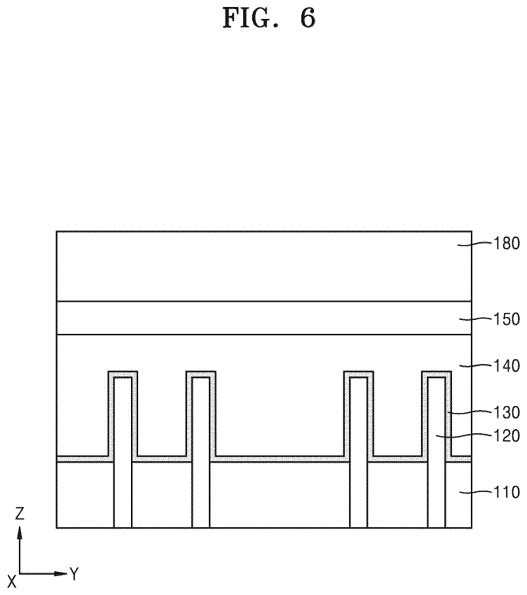

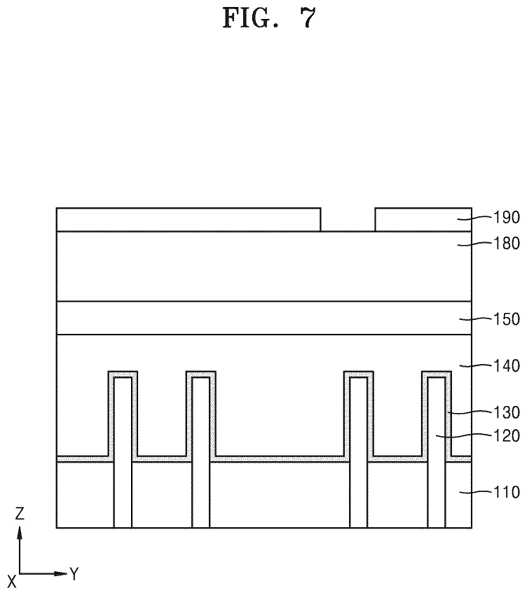

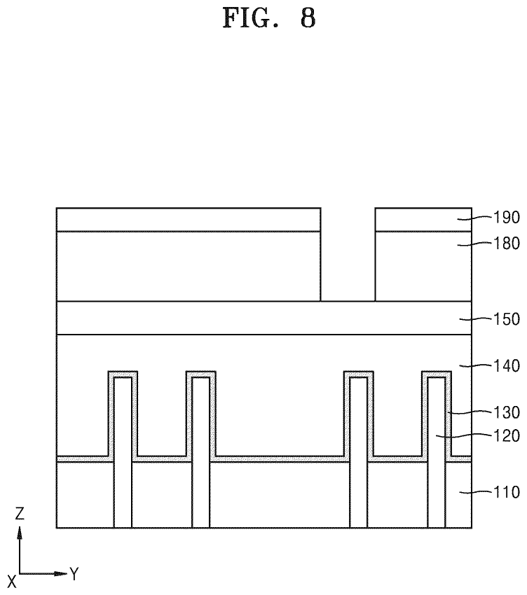

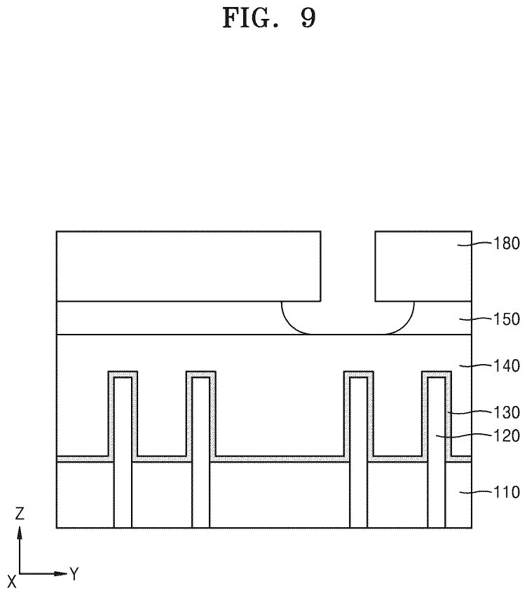

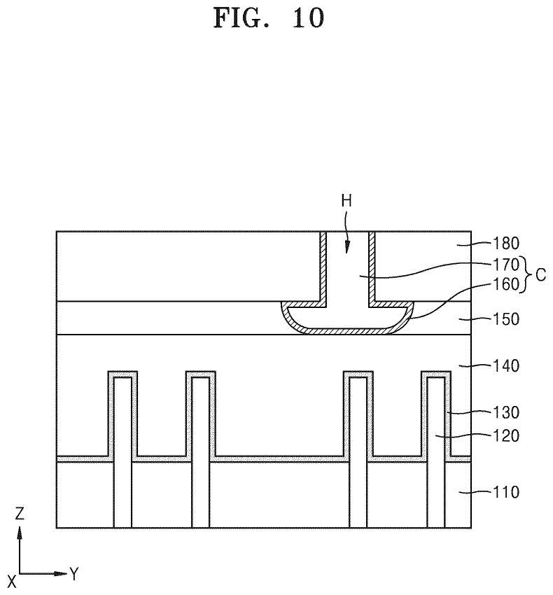

Referring to FIG. 4, a channel 120, an insulating layer 130, and a gate electrode 140 may be provided on a substrate 110, and an etch stop layer 150 may be applied onto the gate electrode 140. Referring to FIG. 5, the etch stop layer 150 applied onto the gate electrode 140 may be partially etched to a certain height in the Z direction. The etching may include a chemical and/or mechanical etching. Referring to FIG. 6, a capping layer 180 may be formed on the etch stop layer 150. Referring to FIG. 7, an etch mask 190 having a pattern for selectively etching the etch stop layer 150 and the capping layer 180 may be provided on the capping layer 180. Referring to FIG. 8, the capping layer 180 provided under the etch mask 190 may be anisotropically etched along the pattern of the etch mask 190. An opening may be provided by etching the capping layer 180 along the pattern of the etch mask 190 in the Z direction, and the etch stop layer 150 provided under the capping layer 180 may be exposed. At this time, the capping layer 180 and the etch stop layer 150 may be formed of materials having selectivity, so that only the capping layer 180 is etched and the etch stop layer 150 is not etched. Referring to FIG. 9, the etch stop layer 150 provided under the opening of the capping layer 180 may be isotropically etched. The etch stop layer 150 may be etched in all directions from the top surface thereof and may be etched until the top surface of the gate electrode 140 is exposed. At this time, the etch stop layer 150 and the capping layer 180 may be formed of materials having selectivity, so that only the etch stop layer 150 is etched and the capping layer 180 is not etched. Referring to FIG. 10, a gate contact plug C may be formed by providing a barrier metal 160 and a metal material 170 in a contact hole H formed by etching the capping layer 180 and the etch stop layer 150.

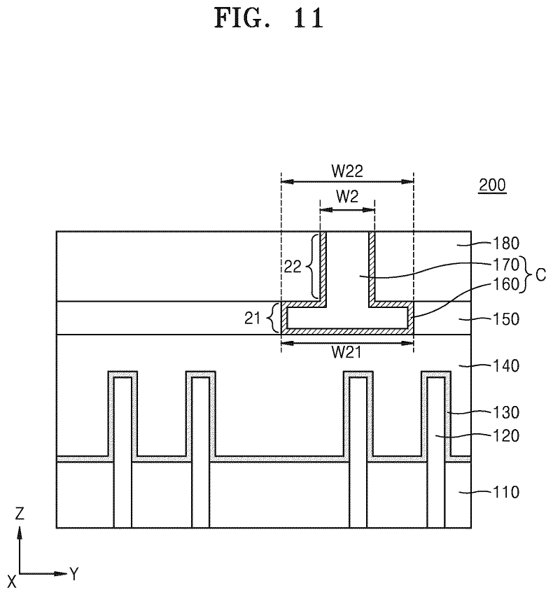

FIG. 11 is an on gate cut cross-sectional view of a gate contact structure 200 according to at least one embodiment. The differences from FIG. 2 are mainly described and the same reference numbers denote the same elements.

Referring to FIG. 11, a gate contact plug C may include a first portion 21 passing through an etch stop layer 150 and a second portion 22 passing through a capping layer 180. The lower part of the first portion 21 may be provided on a top surface of a gate electrode 140. The upper part of the first portion 21 may be provided below a bottom surface of the capping layer 180.

On the other hand, as illustrated in FIG. 11, a width W21 of the lower part of the first portion 21 may be approximately (e.g., substantially) equal and/or similar to a width W22 of the upper part of the first portion 21. At this time, as in FIG. 2, a width W2 of the second portion 22 may be less than the widths W21 and W22 of the first portion 11. When viewed from the Z direction, the area of the first portion 21 of the gate contact plug C passing through the etch stop layer 150 may be greater than the area of the second portion 22 of the gate contact plug C passing through the capping layer 180.

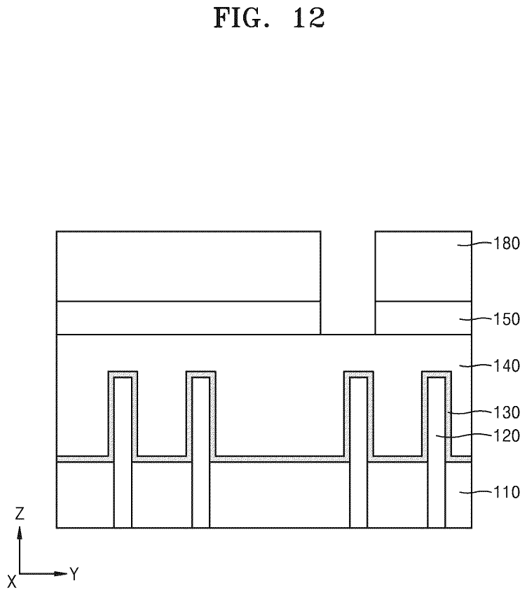

FIGS. 12 to 14 are diagrams illustrating a method of manufacturing the gate contact structure 200 of FIG. 11. The following description is given with reference to FIGS. 4 to 8.

The method of manufacturing the gate contact structure 200 is the same up to the operation of etching the capping layer 180 of the gate contact structure 100 of FIGS. 4 to 8. That is, as illustrated in FIG., the channel 120, the insulating layer 130, and the gate electrode 140 may be provided on the substrate 110, the etch stop layer 150 may be applied onto the gate electrode 140, and then, as illustrated in FIG. 5, the etch stop layer 150 applied onto the gate electrode 140 may be partially etched to a certain height in the Z direction. Thereafter, referring to FIG. 6, the capping layer 180 may be formed on the etch stop layer 150. Referring to FIG. 7, the etch mask 190 having a pattern for selectively etching the etch stop layer 150 and the capping layer 180 may be provided on the capping layer 180. Referring to FIG. 8, the capping layer 180 provided under the etch mask 190 may be anisotropically etched along the pattern of the etch mask 190. The opening may be provided by etching the capping layer 180 along the pattern of the etch mask 190 in the Z direction, and the etch stop layer 150 provided under the capping layer 180 may be exposed. At this time, the capping layer 180 and the etch stop layer 150 may be formed of materials having selectivity, so that only the capping layer 180 is etched and the etch stop layer 150 is not etched.

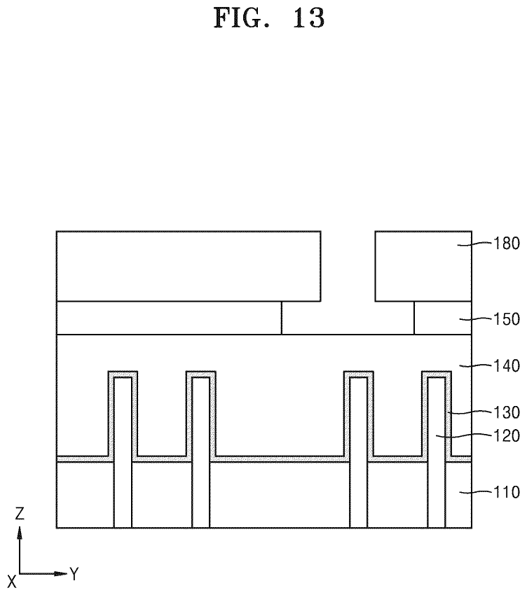

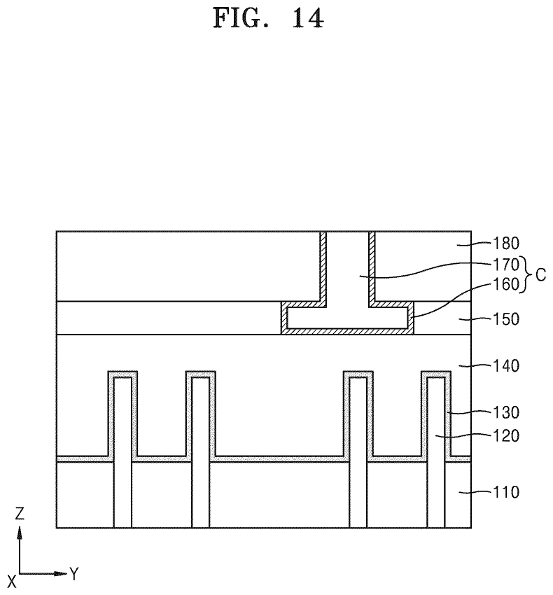

Thereafter, the etch stop layer 150 provided under the opening of the capping layer 180 may be anisotropically etched. After the etch stop layer 150 is anisotropically etched, the etch stop layer 150 may be isotropically etched, as illustrated in FIG. 13. Thereafter, as illustrated in FIG. 14, the gate contact plug C may be formed by providing the barrier metal 160 and the metal material 170 in the contact hole H formed by etching the capping layer 180 and the etch stop layer 150.

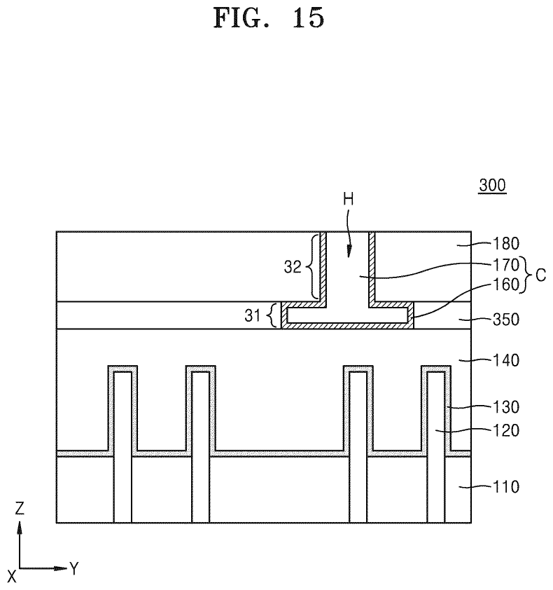

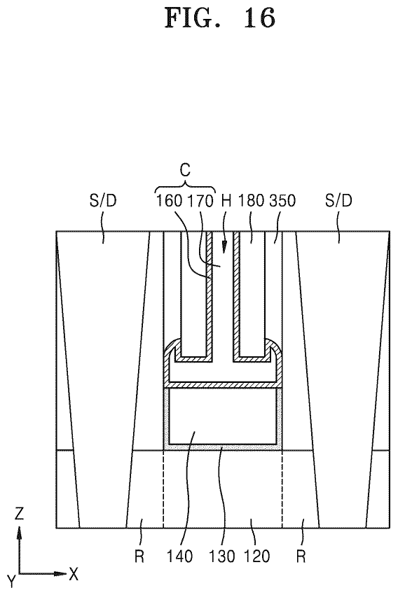

FIG. 15 is an on gate cut cross-sectional view of a gate contact structure 300 according to at least one embodiment and FIG. 16 is an on active cut cross-sectional view of the gate contact structure 300 of FIG. 15. The differences from FIG. 11 are mainly described and the same reference numbers denote the same elements.

Referring to FIGS. 15 and 16, an etch stop layer 350 may be provided not only on an upper surface of a gate electrode 140 but also on an outer surface of a capping layer 180.

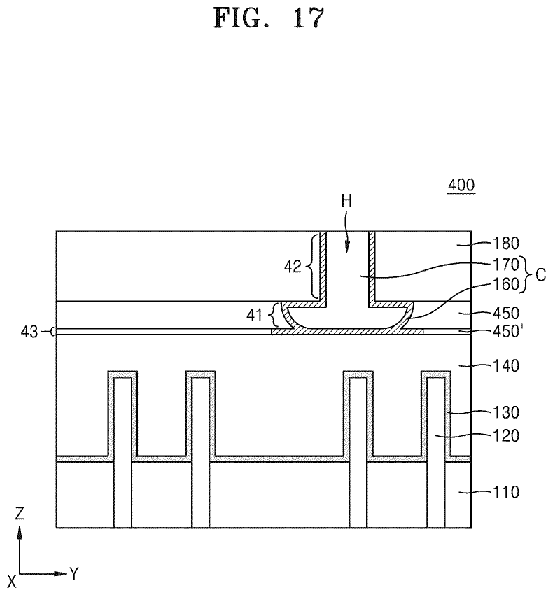

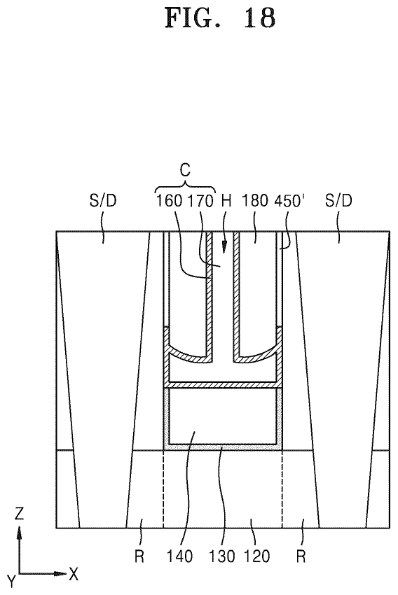

FIG. 17 is an on gate cut cross-sectional view of a gate contact structure 400 according to at least one embodiment and FIG. 18 is an on active cut cross-sectional view of the gate contact structure 400 of FIG. 17. The differences from FIG. 2 are mainly described and the same reference numbers denote the same elements.

Referring to FIGS. 17 and 18, an etch stop layer may include a plurality of layers. For example, as illustrated in FIG. 17, a first etch stop layer 450′may be provided on a gate electrode 140 and a second etch stop layer 450 may be provided on the first etch stop layer 450′. A contact hole may include a first portion 41 provided in the second etch stop layer 450, a second portion 42 provided in a capping layer 180, and a third portion 43 provided in the first etch stop layer 450′. As illustrated in FIG. 18, the first etch stop layer 450′may also be provided on the outer surface of the capping layer 180. The first etch stop layer 450′may include an extension portion provided along the Z direction perpendicular to the upper surface of the gate electrode 140. The second etch stop layer 450 may be identical to or similar to the etch stop layer 150 described above.

A gate contact plug C of the gate contact structure 400 may be formed by anisotropically etching the capping layer 180, isotropically etching the second etch stop layer 450 provided under the capping layer 180, anisotropically etching the first etch stop layer 450′provided under the second etch stop layer 450, and then providing a barrier metal 160 and a metal material 170 in the contact hole H formed by etching the capping layer 180, the second etch stop layer 450, and the first etch stop layer 450′.

The width of the first portion 41 of the contact hole H provided in the second etch stop layer 450 may be greater than the width of the second portion 42 provided in the capping layer 180. The width of the lower part of the first portion 41 may be less than the width of the upper part of the first portion 41. For example, as illustrated in FIG. 17, the width of the first portion 41 of the contact hole H provided in the second etch stop layer 450 may gradually decrease from the top to the bottom. The width of the third portion 43 of the contact hole H provided in the first etch stop layer 450′may be greater than the width of the seco first portion 41 of the contact hole H provided in the second etch stop layer 450.

The first etch stop layer 450′and the second etch stop layer 450 may include different materials. For example, the first etch stop layer 450′may include at least one selected from AlO, AlN, TiO₂, TiN, and/or a combination thereof and the second etch stop layer 450 may include at least one selected from SiO₂, SiOCN, SiON, SiOC, SiCN, and/or a combination thereof. In at least some examples, when the second etch stop layer 450 does not include SiO₂, the first etch stop layer 450′may include SiO_{2.}

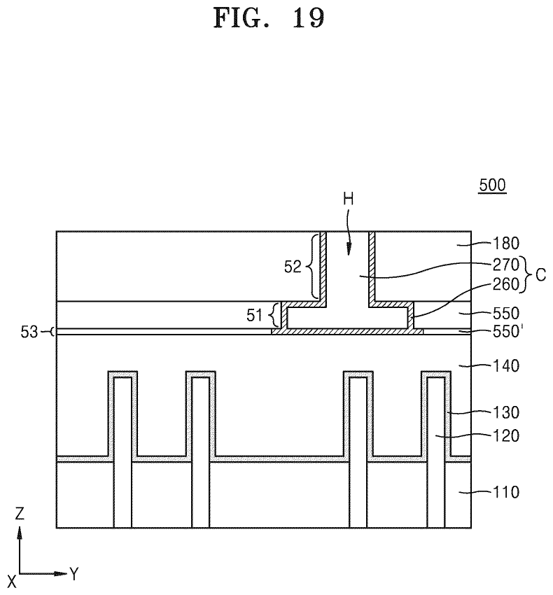

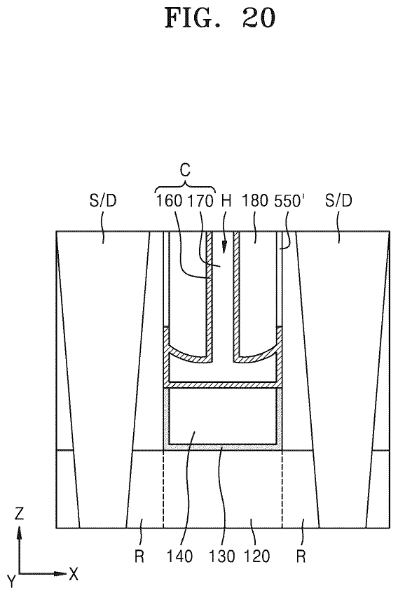

FIG. 19 is an on gate cut cross-sectional view of a gate contact structure 500 according to at least one embodiment and FIG. 20 is an on active cut cross-sectional view of the gate contact structure 500 of FIG. 19. The differences from FIGS. 17 and 18 are mainly described and the same reference numbers denote the same elements.

Referring to FIGS. 19 and 20, an etch stop layer may include a plurality of layers. For example, as illustrated in FIG. 19, a first etch stop layer 550′may be provided on a gate electrode 140 and a second etch stop layer 550 may be provided on the first etch stop layer 550′. As illustrated in FIG. 20, the first etch stop layer 550′may also be provided on an outer surface of a capping layer 180. The second etch stop layer 550 may be identical to or similar to the etch stop layer 150 described above.

A gate contact plug C of the gate contact structure 500 may be formed by anisotropically etching the capping layer 180, anisotropically etching the second etch stop layer 550 provided under the capping layer 180, isotropically etching the second etch stop layer 550, and then isotropically etching the first etch stop layer 550′provided under the second etch stop layer 550 to form a contact hole H, and providing a barrier metal 160 and a metal material 170 in the contact hole H.

A width of a first portion 51 of the contact hole H provided in the second etch stop layer 550 may be greater than a width of a second portion 52 provided in the capping layer 180. widths of the upper part and the lower part of the first portion 51 of the contact hole H provided in the second etch stop layer 550 may be approximately equal to each other. A width of a third portion 53 of the contact hole H provided in the first etch stop layer 550′may be greater than a width of the first portion 51 provided in the second etch stop layer 550.

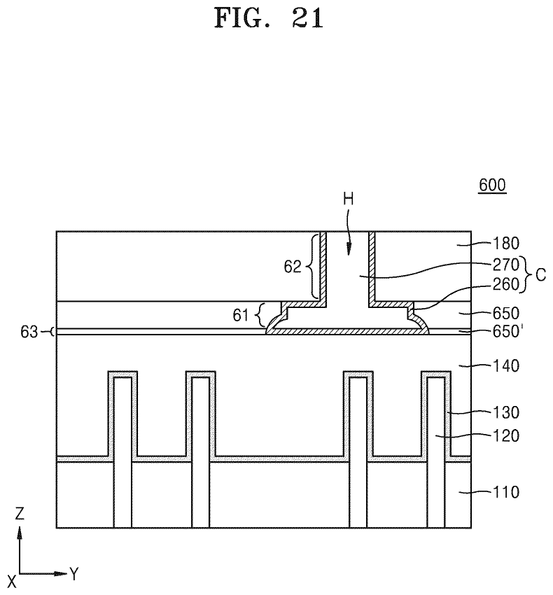

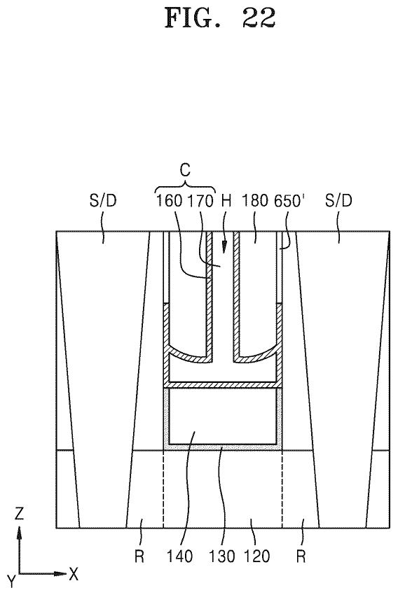

FIG. 21 is an on gate cut cross-sectional view of a gate contact structure 600 according to at least one embodiment and FIG. 22 is an on active cut cross-sectional view of the gate contact structure 600 taken along line B-B′ of FIG. 1. The differences from FIGS. 19 and 20 are mainly described and the same reference numbers denote the same elements.

Referring to FIGS. 21 and 22, an etch stop layer may include a plurality of layers. For example, as illustrated in FIG. 21, a first etch stop layer 650′may be provided on a gate electrode 140 and a second etch stop layer 650 may be provided on the first etch stop layer 650′. As illustrated in FIG. 22, the first etch stop layer 650′may also be provided on an outer surface of a capping layer 180. The second etch stop layer 650 may be identical to or similar to the etch stop layer 150 described above.

A gate contact plug C of the gate contact structure 600 may be formed by anisotropically etching the capping layer 180, isotropically etching the second etch stop layer 650 provided under the capping layer 180, isotropically etching the first etch stop layer 650′provided under the second etch stop layer 650, isotropically etching the second etch stop layer 650 and the first etch stop layer 650′together to form a contact hole H, and then providing a barrier metal 160 and a metal material 170 in the contact hole H.

A width of a first portion 61 of the contact hole H provided in the second etch stop layer 650 may be greater than a width of a second portion 62 provided in the capping layer 180. A width of the first portion 61 of the contact hole H provided in the second etch stop layer 650 may be greater at the lower part than at the upper part. For example, the width of the first portion 61 of the contact hole H provided in the second etch stop layer 650 may be approximately constant and then gradually increase from the top to the bottom. A width of a third portion 63 of the contact hole H provided in the first etch stop layer 650′may be approximately equal to a width of the lower part of the first portion 61 provided in the second etch stop layer 650.

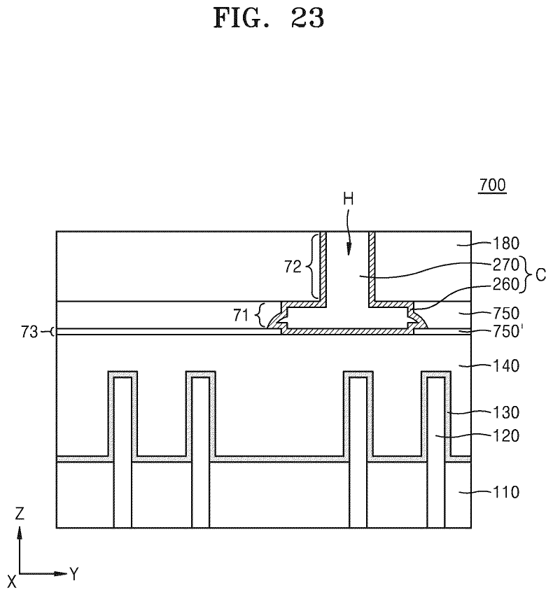

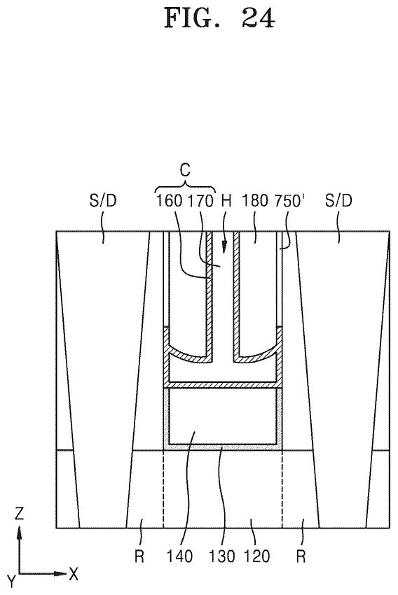

FIG. 23 is an on gate cut cross-sectional view of a gate contact structure 700 according to at least one embodiment and FIG. 24 is an on active cut cross-sectional view of the gate contact structure 700 of FIG. 23. The differences from FIGS. 21 and 22 are mainly described and the same reference numbers denote the same elements.

Referring to FIGS. 23 and 24, an etch stop layer may include a plurality of layers. For example, as illustrated in FIG. 21, a first etch stop layer 750′may be provided on a gate electrode 140 and a second etch stop layer 750 may be provided on the first etch stop layer 750′. As illustrated in FIG. 24, the first etch stop layer 750′may also be provided on an outer surface of a capping layer 180. The second etch stop layer 750 may be identical to or similar to the etch stop layer 150 described above.

A gate contact plug C of the gate contact structure 700 may be formed by anisotropically etching the capping layer 180, isotropically etching the second etch stop layer 750 provided under the capping layer 180, isotropically etching the first etch stop layer 750′provided under the second etch stop layer 750, and isotropically etching the second etch stop layer 750 to form a contact hole H, and then providing a barrier metal 160 and a metal material 170 in the contact hole H.

The width of a first portion 71 of the contact hole H provided in the second etch stop layer 750 may be greater than the width of a second portion 72 provided in the capping layer 180. The width of the first portion 71 of the contact hole H provided in the second etch stop layer 750 may be greater at the lower part than at the upper part. For example, the width of the first portion 71 of the contact hole H provided in the second etch stop layer 750 may be approximately constant and then gradually increase from the top to the bottom. The width of a third portion 73 of the contact hole H provided in the first etch stop layer 750′may be less than the width of the lower part of the first portion 71 provided in the second etch stop layer 750.

In a gate contact structure and a method of manufacturing the same according to at least one embodiment, an etch stop layer having a high selectivity with respect to a capping layer is provided between the capping layer and a gate electrode, and thus, a phenomenon in which the capping layer is not sufficiently etched or is excessively etched up to the gate electrode due to the thickness and dispersion of the capping layer when forming a contact hole in a semiconductor structure may be prevented and/or mitigated.

In addition, in a gate contact structure and a method of manufacturing the same according to at least one embodiment, a first portion of a contact hole provided in an etch stop layer is formed to have a width greater than a width of a second portion provided in a capping layer, and thus, the contact resistance of the gate contact structure may be improved and the capacitance thereof may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A gate contact structure comprising:
a gate electrode;
an etch stop layer above the gate electrode;
a capping layer above the etch stop layer;
a contact hole comprising a first portion defined by the etch stop layer and in contact with the gate electrode and a second portion defined by the capping layer and communicating with the first portion; and
a gate contact plug in the contact hole,
wherein a width of the first portion is greater than a width of the second portion.

2. The gate contact structure of claim 1, wherein
the first portion of the contact hole includes a first part adjacent to the capping layer and a second part adjacent to the gate electrode, and
a width of the first part of the first portion is greater than a width of the second part of the first portion.

3. The gate contact structure of claim 1, wherein
the first portion includes a first part adjacent to the capping layer and a second part adjacent to the gate electrode, and
a width of the first part of the first portion is equal to a width of the second part of the first portion.

4. The gate contact structure of claim 1, wherein the etch stop layer comprises an extension portion extending in a direction perpendicular to a surface of the gate electrode.

5. The gate contact structure of claim 1, wherein
the capping layer comprises SiN, and
the etch stop layer comprises at least one of SiO₂, SiOCN, SiON, SiOC, SiCN, or a combination thereof.

6. The gate contact structure of claim 1, wherein the etch stop layer comprises a first etch stop layer and a second etch stop layer, wherein the first etch stop layer is above the gate electrode and the second etch stop layer is above the first etch stop layer.

7. The gate contact structure of claim 6, wherein
the capping layer comprises SiN,
the first etch stop layer comprises at least one of AlO, AlN, TiO₂, TiN, SiO₂, or a combination thereof, and
the second etch stop layer comprises at least one of SiO₂, SiOCN, SiON, SiOC, SiCN, or a combination thereof.

8. The gate contact structure of claim 6, wherein
the first portion of the contact hole is in the second etch stop layer and includes a first part adjacent to the capping layer and a second part adjacent to the gate electrode,
the contact hole further comprises a third portion in the first etch stop layer,
a width of the first part of the first portion is less than a width of the second part of the first portion, and
a width of the third portion is greater than the width of the second part of the first portion.

9. The gate contact structure of claim 6, wherein
the first portion of the contact hole is in the second etch stop layer,
the contact hole further comprises a third portion in the first etch stop layer, and
a width of the third portion is greater than a width of the first portion.

10. The gate contact structure of claim 6, wherein
the first portion of the contact hole is in the second etch stop layer and includes a first part adjacent to the capping layer and a second part adjacent to the gate electrode,
the contact hole further comprises a third portion in the first etch stop layer,
a width of the second part of the first portion is greater than a width of the first part of the first portion, and a width of the third portion is equal to the width of the second part of the first portion.

11. The gate contact structure of claim 6, wherein
the first portion is in the second etch stop layer and includes a first part adjacent to the capping layer and a second part adjacent to the gate electrode,
the contact hole further comprises a third portion in the first etch stop layer,
a width of the second part of the first portion is greater than a width of the first part of the first portion, and
a width of the third portion is less than the width of the second part of the first portion.

12. A method of manufacturing a gate contact structure, the method comprising:
providing an etch stop layer on a gate electrode;
providing a capping layer on the etch stop layer;
forming a first portion of a contact hole by etching the capping layer;
forming a second portion of the contact hole by etching the etch stop layer; and
forming a gate contact plug within the contact hole,
wherein a width of the first portion is greater than a width of the second portion.

13. The method of claim 12, wherein
the etching of the capping layer comprises anisotropically etching the capping layer, and
the etching of the etch stop layer comprises isotropically etching the etch stop layer.

14. The method of claim 12, wherein the etching of the etch stop layer comprises:
anisotropically etching the etch stop layer; and
isotropically etching the etch stop layer.

15. The method of claim 12, wherein
the providing of the etch stop layer on the gate electrode comprises
providing a first etch stop layer on the gate electrode; and
providing a second etch stop layer on the first etch stop layer, and
wherein the etching of the etch stop layer comprises
isotropically etching the second etch stop layer; and
isotropically etching the first etch stop layer.

16. The method of claim 12, wherein the providing of the etch stop layer on the gate electrode comprises
providing a first etch stop layer on the gate electrode; and
providing a second etch stop layer on the first etch stop layer, and
wherein the etching of the etch stop layer comprises
anisotropically etching the second etch stop layer;
isotropically etching the etched second etch stop layer; and
isotropically etching the first etch stop layer.

17. The method of claim 12, wherein
the providing of the etch stop layer on the gate electrode comprises
providing a first etch stop layer on the gate electrode; and
providing a second etch stop layer on the first etch stop layer,
wherein the etching of the etch stop layer comprises
isotropically etching the second etch stop layer;
isotropically etching the first etch stop layer; and
isotropically etching the etched first etch stop layer and the etched second etch stop layer together.

18. The method of claim 12, wherein
the providing of the etch stop layer on the gate electrode comprises
providing a first etch stop layer on the gate electrode; and
providing a second etch stop layer on the first etch stop layer,
wherein the etching of the etch stop layer comprises
isotropically etching the second etch stop layer;
isotropically etching the first etch stop layer; and
anisotropically etching the etched second etch stop layer.
